(19) United States
(12) Patent Application Publication
(10) Pub. No.: US 2024/0288598 A1
(43) Pub. Date: Aug. 29, 2024

(54) A GEOPHYSICAL DATA ACQUISITION DEVICE

(71) Applicants: Stephen BUSUTTIL, North Adelaide, South Australia (AU); John Edward Ellis KINGMAN, Chiang Wat Sisaket (TH)

(72) Inventors: Stephen BUSUTTIL, North Adelaide, South Australia (AU); John Edward Ellis KINGMAN, Chiang Wat Sisaket (TH)

(21) Appl. No.: 18/566,222

(22) PCT Filed: Jun. 3, 2022
(86) PCT No.: PCT/AU2022/050548

§ 371 Date: Dec. 1, 2023

(30) Foreign Application Priority Data
Jun. 4, 2021 (AU) 2021901678

(51) Int. Cl. G01V 1/22; G01V 1/28

(52) U.S. Cl. CPC G01V 1/22; G01V 1/28

(57) ABSTRACT

A geophysical data acquisition device includes a transducer signal receivers configured to receive signals from different transducers; a wireless receiver; a processor configured to, based on received command or parameter information, determine a selection of transducers from the transducers and process the signals received by each of a set of transducer signal receivers corresponding to the selection of transducers into transducer data corresponding to the transducer associated with the transducer signal receiver; and a data transmitter, wherein each of the transducers is adapted to measure physical phenomena associated with a set and type of geophysical data, wherein the physical phenomena measured by at least one transducer of the transducers are associated with a type of geophysical data that is different to the type of geophysical data associated with the physical phenomena measured by another one transducer of the plurality of transducers.

### TECHNICAL FIELD

The present invention relates to a geophysical data acquisition device.

### BACKGROUND

Geophysical exploration methods, such as electrical, magnetic, electromagnetic and seismic methods, generally aim at obtaining information on physical properties of the Earth subsurface and require the use of equipment which is generally placed at the Earth surface.

The type of geophysical exploration method used generally depends on the type of information to be acquired.

An approach to geophysical exploration methods, such as electrical geophysical methods and seismic methods, consists in a distributed acquisition of geophysical data wherein a relatively large number of sensors or transducers are deployed across a large area (e.g., 10 to 2,000 km²) and hardware component, referred to as a data acquisition device and processing hardware is positioned within a few meters of the transducers for simultaneously measuring the signals from the transducers. Different types of data acquisition and processing hardware are generally required for surveying different types of geophysical data including, e.g., electric field data, magnetic field data, electrical current data, and seismic data.

Geophysical exploration methods may be carried out in challenging conditions, e.g., mountains, desert, jungle, pouring rain, which may also involve ambient temperatures ranging, for example, from −40° C. (a Canadian winter) to about +50° C. (an Australian summer). The equipment required, including the different types of data acquisition and processing hardware and the associated transducers, is often deployed and installed manually. As a result of these conditions, the total mass of equipment to be deployed and the frequency at which the various pieces of equipment must be visited (e.g., to exchange batteries) are two criteria of important concern that generally govern the cost and safety risks associated with the geophysical exploration methods and may further put some limitation on the implementation of the geophysical exploration methods.

### SUMMARY

Embodiments of the present invention seek to provide an improved geophysical data acquisition device and an improved geophysical data acquisition and processing system that allow simultaneously obtaining information on a plurality of different physical phenomena, which are impacted by the petrophysical properties of the Earth's subsurface and are associated with different types of geophysical data, across large areas and in various environmental conditions with a substantially improved accuracy and efficiency in comparison to available geophysical data acquisition devices.

In the context of this application, the terms “physical phenomena” or “physical phenomenon” are intended to, and will be understood to, include any phenomenon that is impacted by the petrophysical properties of the Earth's subsurface. For example, the physical phenomena may include the following: fields including electric field and magnetic field; current flow; ground motion. It will be understood that other physical phenomena as deemed appropriate by a person skilled in the art in the context of this application may also be considered to be within the scope of this application.

In the context of this application, the term “geophysical data” is intended to, and will be understood to, mean data indicative of information on the physical properties of the Earth's surface and subsurface. The term “a type of geophysical data” is intended to, and will be understood to, mean geophysical data that relate to any one of the following categories or types including, however not limited to: electric field data; magnetic field data; electrical data; seismic data. For example, seismic data issued from ground motion phenomena may include translational acceleration data, velocity data, angular and/or rotational motion data, and each of the translational acceleration data, velocity data, angular and/or rotational motion data will be understood to relate to one type of geophysical data which is seismic data. In another example, electrical data may include electrical current data and/or voltage data, and electrical current data and voltage data will each be understood to relate to one type of geophysical data which is electrical data and is different to seismic data. Different types of geophysical data will be understood to mean respective geophysical data associated with or relating to different categories or types. For example, and not limited to, one type of geophysical data may be electric field data and a type of geophysical data that is different from the electric field data may be magnetic data. It will be understood that other types of geophysical data may further be envisaged such as, however not limited to, force or strain (angular and/or ‘cartesian’), and stress (angular and/or ‘cartesian’).

Embodiments of the present invention may have various environmental, geotechnical, engineering and near-surface applications, including, for example, however not limited to: mining applications (e.g., pit-slope stability monitoring (especially via passive seismic measurements), void detection such as when mining in the presence of older underground workings); hydrological applications (e.g., to assist with the monitoring of ground and surface water contamination); tailings dam monitoring; leach-operations monitoring (e.g., mapping leachate, monitoring for leaks in leach pad liners); reclamation planning and monitoring.

To acquire information associated with geophysical data, including for example electric field data, magnetic field data, electrical current data, and seismic data, geophysical exploration methods generally rely on two basic exploration classes:

i) Active or controlled source exploration methods, whereby geophysical phenomena are induced using man-made (synthesized) excitation sources. For electrical geophysical prospecting methods (i.e. exploration methods for acquisition of, e.g. electric field, magnetic field and electrical current data), a typical example may be a current flow induced in the ground wherein 5 kW to 200 kW power sources may be used coupled to a transmitter, which generates a controlled and periodic current waveform. The synthesized current signal either flows into a closed loop or between two electrodes in the ground. Electrical measurements obtained as a result of active excitation sources may for example have a frequency within the range 10⁴ Hz to 200 kHz. For seismic prospecting methods (i.e. exploration methods for acquisition of seismic data), one example may be reflection and refraction seismic methods, which may typically result in seismic data with a frequency band within 1.0 Hz to 1 kHz (3 Hz to 100 Hz is commonly used).

ii) Passive or natural field exploration methods, whereby no man-made excitation source is employed. Time-varying electromagnetic fields in and around the Earth occurring as a result of natural energy sources such as solar winds and impulsive atmospheric discharges referred to as spherics are an example of naturally induced geophysical phenomena. The frequency band of seismic data resulting from passive seismic excitation sources generally extends to a substantially lower range, such as 0.1 Hz to 10 Hz, than in the case of active excitation sources.

In one aspect of the present invention, there is provided a geophysical data acquisition device for acquiring and processing signals from different transducers, the geophysical data acquisition device comprising:
a plurality of transducer signal receivers configured to receive signals from a plurality of different transducers;
a wireless receiver for wirelessly receiving command or parameter information from an external device;
a processor configured to, based on the received command or parameter information, determine a selection of transducers from the plurality of transducers and process the signals received by each of a set of transducer signal receivers corresponding to the selection of transducers into transducer data corresponding to the transducer associated with the transducer signal receiver; and
a data transmitter configured to transmit the transducer data to the external device,
wherein each of the transducers is adapted to measure one or more physical phenomena associated with a set and type of geophysical data, wherein the one or more physical phenomena measured by at least one transducer of the plurality of transducers are associated with a type of geophysical data that is different to the type of geophysical data associated with the one or more physical phenomena measured by at least another transducer of the plurality of transducers.

For each transducer, the term “a set of geophysical data” is intended to, and will be understood to, mean one or more geophysical data that are associated with the one or more physical phenomena measured by the transducer.

In one embodiment, the geophysical data acquisition device further comprises an analog-to-digital converter arranged to digitise the signals received from the plurality of different transducers.

As used herein, the terms “digitise”, “digitised”, “sample” and “sampled” will be used interchangeably to refer to the process of converting signals received from the transducers in an analog form into a digital form, wherein the conversion involves quantization of the signals received from the transducers. The quantization may be characterised by a sampling rate.

In one embodiment, the analog-to-digital converter is arranged to digitise the signals received at the set of transducer signal receivers using sigma-delta modulation. Sigma-delta modulation may be advantageous to act as an anti-aliasing filter in order to help maximize the fidelity of the geophysical data acquisition device in its acquisition and processing of transducer signals. Alternatively, other approaches may be used for carrying out the digitization of the signals.

In some embodiments, the sampling rates at which the signals received by each of the transducer signal receivers from transducers are digitised may range from 1 to 10⁵ up to 2×10⁵ samples-per-second (sps). For example, a maximum sampling rate of between 10⁴ and 10⁵ sps may serve most base-metals exploration surveys. However, it will be understood that sampling rates higher than 2×10⁵ sps are not excluded and may be considered.

In one embodiment, the geophysical data acquisition device further comprises a time base element adapted to generate an output signal usable by the analog-to-digital converter for simultaneously digitising the signals received from the plurality of different transducers.

In one embodiment, the time base element is provided in the form of a slaved oscillator arranged to receive a time signal from a Global Navigation Satellite System (GNSS) or a Global Positioning System (GPS). Alternatively, the time base element may be a time base generator arranged to receive a time signal in the form of a relatively low-frequency (e.g., 150 MHz or less) radio signal that is not disrupted by mountainous topography and is unencumbered by international licensing requirements may be used. In response to receiving the time signal, the time base element is then arranged to generate an output signal indicative of a sampling rate, the output signal causing the analog-to-digital converter to simultaneously digitise the transducer signals. In other words, the output signal causes the analog-to-digital converter to digitise the transducer signals at substantially the same sampling rate.

In one embodiment, the processor is configured, based on the received command or parameter information, to simultaneously process the signals received from the set of transducer signal receivers corresponding to the selection of transducers.

In one embodiment, the wireless receiver is further arranged for wirelessly receiving excitation information, and the processor is configured to use the excitation information to process the signals received from the set of transducer signal receivers in synchronization with the excitation information.

In one embodiment, the analog-to-digital converter may be configured to sample, i.e. digitise the transducer signals in synchronisation with the excitations. To achieve sampling simultaneity and synchronisation of the sampling process with the excitations, the sampling rate must correspond to an integer number of samples per half-period associated with the excitation signal. In one embodiment, the transducer signals comprise respective transducer response signals received from the transducers as a result of the excitation and respective excitation signals. In one embodiment, the excitation signals convey information associated with the source and type of the excitation, such as, however not limited to, excitation base frequency, time at which the excitation started, duration of excitation, time at which the excitation stopped. In one embodiment, an excitation signal is transmitted by a transmitter of the excitation source hardware to the transducers, wherein the geophysical data acquisition device may be at or in the proximity of the excitation source hardware and transmitter. The excitation source hardware may comprise one or more excitation control devices that establish transmitter settings such as, waveform, base frequency, optimal voltage level, start and stop times, etc. In one embodiment, the excitation signal is periodically received from the transducers at the transducer signal receivers. The analog-to-digital converter is arranged to digitise the transducer response signals at substantially the same sampling rate and to digitise the transducer response signals and the excitation signals in synchronisation using a signal processing algorithm (which may be referred to as odd-harmonic stacking) wherein the transducer response signals and the excitation signals are input into the signal processing algorithm. The processor is then configured to determine a selection of the transducers using the commands or parameter information received from the external device, and to simultaneously process the digitised transducer response signals and the digitised excitation signals for the selected transducers into transducer data comprising transducer response data and excitation data.

Alternatively, or simultaneously, the wireless receiver may further be arranged to receive excitation information. The processor may be configured to use the received excitation information to process the digitised transducer response signals (transducer response signals digitised at substantially the same sampling rate) corresponding to the selection of transducers simultaneously and in synchronisation with the excitation information. In this embodiment, the excitation information may be received from another geophysical data acquisition device positioned to measure the same excitation. Alternatively, the excitation information may be received from the excitation source hardware via a wireless communication means such as a wireless communications network or, wherein distances allow, using wireless technology such as Bluetooth® or any other alternative short-range wireless means of technology.

In another alternative embodiment, the excitation information may be received at the wireless receiver from the external device via a wireless communications network or, wherein distances allow, using wireless technology such as Bluetooth® or any other alternative short-range wireless means of technology.

In one embodiment, the data transmitter is configured to wirelessly transmit the transducer data to the external device.

In one embodiment, the processor is further arranged to compress the transducer data and the data transmitter is configured to wirelessly transmit the transducer data to the external device in a compressed form.

The data transmitter may be configured to wirelessly transmit the transducer data to the external device using a low-power wide-area communications network.

In one embodiment, the external device may be a computer located at a central control facility wherein an operator governs operations and monitors data quality. The central control facility may also be referred to herein as a base station.

In an alternative embodiment, the external device may be a relay station (such as, e.g., a gateway, a hub, a node, or a repeater) acting as an intermediary between the geophysical data acquisition device and a central control facility. Where the external device is a relay station, it may be arranged to boost incoming and/or outgoing signals between the geophysical data acquisition device and the central control facility.

In another alternative embodiment, the external device may be a local device communicating with the geophysical data acquisition device. For example, the external device may be a lightweight handheld computer either under the control of a person or, alternatively, mounted to an unmanned airborne or ground vehicle.

In one embodiment, the geophysical data acquisition device further comprises a data storage for storing the command or parameter information. The data storage may further be arranged to store the received excitation information, wherein the processor is configured to retrieve the excitation information from the data storage to process the signals received from the set of transducer signal receivers. The data storage may further be arranged to store the transducer data. The data storage may comprise one or more storage media for storing, respectively, the command or parameter information, the received excitation information, data associated with the digitised signals output from the analog-to-digital converter including timestamps, and the transducer data.

One or more storage media of the data storage may be configured to have relatively high write speeds depending on the sampling rate to keep up with the output digitised signals for all channels, i.e. all transducer signal receivers. For example, a storage medium of the data storage may be configured to have a write speed in a range between 1 million bytes per second (MB/s) and 100 MB/s. However, it will be understood that any other write speed is envisaged, as may be deemed appropriate by a person skilled in the art.

The data storage may comprise one or more fast storage media. The data storage may further comprise non-volatile memory for permanently storing, for example however not limited to, computer program instructions usable by the processor. In one embodiment, the data storage may include one or more high-speed memory buffers and a non-volatile memory wherein data (including the command or parameter information, the received excitation information, data associated with the digitised signals output from the analog-to-digital converter including timestamps, and the transducer data) can be written to the high-speed memory buffers during the data acquisition, i.e. as the data are acquired, and can then simultaneously be transferred to the permanent non-volatile memory at a slower writing speed.

In one embodiment, the geophysical data acquisition device comprises at least four receivers, each receiver being configured to receive signals from a respective transducer.

In one embodiment, the set of geophysical data includes electric field data, magnetic field data, and electrical current data. The set of geophysical data may further include seismic data.

The different transducers may include any one or more of the following types of transducers: an electric field transducer; a magnetic field transducer; and an electrical current transducer. The different transducers may further include at least one ground motion transducer.

In an embodiment, each different transducer may comprise any one or more of the following types of transducers: an electric field transducer; a magnetic field transducer; and an electrical current transducer. The different transducers may further include at least one ground motion transducer.

As used herein, the term “a type of transducer” is intended to, and will be understood to, refer to a transducer adapted to measure one or more physical phenomena associated with a single type of geophysical data, e.g. electric field data. For example, transducers, which may be different however are all adapted to measure physical phenomena associated with electric field data are in the context of this specification understood to relate to one type of transducer. In another example, transducers, which may be different however are all adapted to measure physical phenomena associated with electrical current data are in the context of this specification understood to relate to another type of transducer. Different transducers adapted to measure physical phenomena associated with a same type of geophysical data are in the context of this specification understood to be transducers of a same type. For example, transducers adapted to measure physical phenomena associated with electric field data are of one type. Respective transducers that are adapted to measure physical phenomena associated with different types of geophysical data are in the context of this specification understood to be different types of transducers. For example, transducers adapted to measure physical phenomena associated with electric field data are of one type. Transducers adapted to measure physical phenomena associated with magnetic field data are of another type different from the type of transducers adapted to measure physical phenomena associated with electric field data.

As used herein, the term “electric field transducer(s)” is intended to, and will be understood to, mean transducers that are adapted to measure physical phenomena associated with geophysical data of the type that is electric field data.

As used herein, the term “magnetic field transducer(s)” is intended to, and will be understood to, mean transducers that are adapted to measure physical phenomena associated with geophysical data of the type that is magnetic field data.

As used herein, the term “electrical current transducer(s)” is intended to, and will be understood to, mean transducers that are adapted to measure physical phenomena associated with geophysical data of the type that is electrical current data.

As used herein, the term “ground motion transducer(s)” is intended to, and will be understood to, mean transducers that are adapted to measure physical phenomena associated with geophysical data of the type that is ground motion data.

The or each electric field transducer may comprise a grounded dipole (which measures a voltage between two separated electrodes in the ground) and/or an ungrounded dipole (which uses charge-coupled amplifiers).

The or each magnetic field transducer may comprise one or more of a large area (e.g. 100 m²) single-turn induction loop, multi-turn passive induction coils, multi-turn active (amplified) induction coils, current-amplified search coils, flux-feedback search coils, fluxgate magnetometers, optically pumped alkali vapor total field magnetometers, high-temperature and low-temperature SQUID magnetometers, or spintronics giant magneto-resistive (GMR).

The or each electrical current transducer may comprise one or more of shunt and Kelvin (four-terminal) resistors, zero-flux fluxgate detectors, Hall effect sensors, or a Rogowski coil.

The or each ground motion transducer may comprise one or more of a mechanical geophone, or various classes of accelerometers both single component and 3-component.

In one embodiment, one or more of the transducers are equipped with their own respective isolated power supply.

In one embodiment, each transducer signal receiver of the geophysical data acquisition device is equipped with its own respective power supply, and the power supplies of all transducer signal receivers are coupled to a same battery.

In one embodiment, the or each transducer is configured to produce an analog voltage output in response to some excitation source. In this embodiment, the geophysical data acquisition device may comprise a front-end analog signal conditioning means. The front-end analog signal conditioning means may be configured to ensure a commensurate level of noise cancellation and may comprise filtering elements. The filtering elements may include low-pass filtering elements providing substantially linear and time-invariant low-pass filtering (e.g., approximately less than 10⁻⁶ non-linear distortion) at a number of selectable but fixed corner frequencies (e.g., four to eight selectable but fixed corner frequencies). In one embodiment, the corner frequencies of the linear low-pass filtering are commensurate with the sampling rate in use and the linear low-pass filtering has characteristics that are not impacted by the output impedance of the transducer being measured. The filtering elements may further include one or more high pass filtering elements, such as a 3 Hz high-pass filter, which may be appropriate for signal base frequencies greater than 10 Hz. In one embodiment, stable, time-invariant linear distortion (once a corner frequency is selected) is known in a substantially accurate manner to allow for a calibration of the digital signals in a substantially precise manner when referring to volts at the input.

In one embodiment, the signals output by the transducers are received by the transducer signal receivers with a constant and frequency-independent input impedance. For example, a constant and frequency-independent input impedance of approximately 10⁶Ω may be enabled at the transducer signal receivers. A stable input impedance may in particular be advantageous for measurements involving an acquisition of electrical field data, wherein a grounded dipole may be used as a transducer. Further, to ensure an appropriate level of input impedance and provide gain when needed in the front-end analog signal conditioning, the front-end analog signal conditioning means may further comprise some operational amplifiers.

In another embodiment, the plurality of transducers may comprise at least some transducers that are configured to generate a digital signal. In this embodiment, the geophysical data acquisition device may further comprise a digital I/O interface that is configured to receive and store the digital signal data received from the transducers by the transducer signal receivers.

In one embodiment, each transducer is connected to the geophysical data acquisition device by means of a wire connection.

In some embodiments, at least some of the transducers may be configured to wirelessly receive and/or transmit data from/to the geophysical data acquisition device and/or the external device. For example, local wireless communications may be enabled between the geophysical data acquisition device and the transducers with selectable settings. These settings may make it possible, for example, to remotely switch between two or more different transducers, or to remotely disconnect wires & cables because of local lightning activity, or to remotely set off a hidden external alarm if theft is suspected. In this embodiment, the geophysical data acquisition device may be arranged to receive commands from the external device at the wireless receiver, wherein the received commands cause the processor to determine a new selection of transducers. In the embodiment wherein the received commands are indicative of instructions to disconnect a connection between the geophysical data acquisition device and the transducers, the processor may further be configured to generate an output signal using the received commands.

In the embodiment where the transducers are connected to the geophysical data acquisition device by means of a wire connection, the output signal may be used by the digital I/O interface to cause one or more of the transducer signal receivers to disconnect or interrupt the wire connection to the transducers.

Alternatively, where the transducers are configured to wirelessly receive and/or transmit data, the output signal generated by the processor may be wirelessly transmitted to the transducers causing the transducers to stop measuring.

In one embodiment, the wireless receiver and data transmitter are part of one unit having wireless transmission and receiving capabilities.

In one embodiment, the geophysical data acquisition device further comprises a surge protection means.

In one embodiment, the geophysical data acquisition device further comprises a fault detection means.

The geophysical data acquisition device in accordance with embodiments of the present invention is arranged to acquire a large number of signals from a number of different transducers and to process a corresponding large amount of data, including data relating to different types of geophysical data. In one embodiment, to allow for a transmission of the transducer data wirelessly over large distances while maintaining accuracy and precision of the transducer data and with minimal loss of data, wireless communication between the external device and the geophysical data acquisition device is enabled via a low power wide area communications network (LPWAN). An LPWAN may indeed be particularly advantageous for long-range, multi-hop wireless communications between a geophysical data acquisition device and the external device.

Further, in one embodiment, the transducer data may be compressed prior to transmission to the external device. In this embodiment, the processor further comprises a data compressor that is configured to compress the transducer data using one or more data compression schemes providing substantially lossless compression optimised for integer time-series. The data compression aims at yielding maximized effective information content in a relatively small number of bytes. For example, in a specific example, a plurality of gigabytes of transducer data may be compressed using one or more data compression schemes to a single bit either 0 or 1, with 0 meaning that the transducer data are corrupted, i.e. not valuable, and 1 meaning that the data are good, i.e. valuable. The data compression further aims at facilitating a transmission of the transducer data to the external device via an LPWAN, which must be slow to reserve power, while serving quality assurance requirements over long distances.

In the embodiment where the transducer signals comprise respective transducer response signals received from the transducers (as a result of the excitation) and respective excitation signals, the data compressor may be configured to compress the transducer response data and the excitation data using one or more data compression schemes providing substantially lossless compression optimised for integer time-series. In this embodiment, the data transmitter may be configured to wirelessly transmit the compressed transducer response data and compressed excitation data to the external device and the transducer excitation data may be further transmitted to another geophysical data acquisition device.

In one embodiment, the geophysical data acquisition device is configured to acquire and process the signals received from the transducers into transducer data in real-time, on-the-fly.

In another embodiment where distances between the geophysical data acquisition device and the external device are relatively short-range, communications between the geophysical data acquisition device and the external device may be facilitated using Bluetooth® technology, or alternatively any other short-range, wireless means of technology. Such enabled communication may be used for example in an embodiment wherein the external device is an operator's wireless device or unmanned aerial vehicle.

In one embodiment, it is also envisaged that the geophysical data acquisition device and the external device be in network communication via hardwire connection. Network communication via hardwire connection may be enabled via an Ethernet cable, serial or parallel cable, or any other means as deemed appropriate by a person skilled in the art.

Network communication via hardwire connection between the geophysical data acquisition device and the external device may be advantageously used for high station density operational modes where the ground is imaged with maximum resolution and contiguous dipoles are employed as transducers for example.

The geophysical data acquisition device may further be equipped with a state-of-health monitor configured to carry out state-of-health monitoring using respective state-of-health algorithms. The state-of-health monitor may be configured to carry out monitoring of the following, the list being non-exclusive:
battery voltage and expected remaining life
power supplies and various voltage checks
network (when active)
ADC built in self-checks
sensor impedance (generally on-command)
over-scales (high side and low side)
integrity of essential files (e.g. SHA-256 hash signatures)
internal memory integrity
surge-protection circuitry

Further, the geophysical data acquisition device may be arranged to function according to various modes of operation including:
a listening while sleep mode
a listening while active mode
a timed off mode
a networked mode
an autonomous mode (logger—no network communications)
a reduced power mode (e.g. a selection of transducers disabled) The term “sleep mode” may also be referred to as inactive mode.

The term “active” in the context of this application is intended to mean:
a) the geophysical data acquisition device is turned on and fully functioning, able to acquire and store data, with network communications enabled; or
b) the geophysical data acquisition device is turned off to save power but the network communications are enabled; or
c) the network communications are disabled (timed off) but the geophysical data acquisition device is turned on and fully functioning.

A networked mode is intended to mean that network communications are enabled.

In one embodiment, the data storage is further configured to store data associated with the state of heath information, fault reports, battery history, communications/network health, internal temperature, and any other data received and/or processed within the geophysical data acquisition device.

It is envisaged that the geophysical data acquisition device in accordance with embodiments of the present invention be relatively light, and may for example weigh less than 2 kg, be not too bulky and easy to transport. In an embodiment, the geophysical data acquisition device may a maximum volume of approximately 3500 cm³ and/or have a maximum linear dimension of 30 cm. The geophysical data acquisition device can be operable in harsh conditions such as one or more of: (i) temperatures ranging from −40 C° to 50° C., (ii) pouring rain, and (iii) be substantially waterproof, e.g. waterproof in 50 cm of water or less.

Embodiments of the geophysical data acquisition device and geophysical data acquisition and processing system, when applied to survey measurements of electric field, may be applicable to corresponding transducers with a variety of electrode geometries. For example, an arrangement of three electrodes serving two orthogonal dipoles, whereby one electrode serves both dipoles. Further, in another example, contiguous, shared-electrode dipoles whereby most dipoles employ electrodes that are also employed by two or more additional dipoles are envisaged. For example, one of any number of related geometries is N dipoles employing N+1 electrodes whereby all except the end-most electrodes are shared by two dipoles.

In another aspect of the present invention, there is provided a geophysical data acquisition and processing system comprising:
a plurality of different transducers, each of which is adapted to measure one or more physical phenomena associated with a set and type of geophysical data, wherein the one or more physical phenomena measured by at least one transducer of the plurality of different transducers are associated with a type of geophysical data that is different to the type of geophysical data associated with the one or more physical phenomena measured by at least another transducer of the plurality of transducers;
a plurality of geophysical data acquisition devices, each geophysical data acquisition device being for acquiring and processing signals from a set of the plurality of transducers into transducer data, and each geophysical data acquisition device being in accordance with embodiments of the first aspect; and
a geophysical data processing server configured to receive and process the transducer data from the plurality of geophysical data acquisition devices.

Each transducer may be any type of transducer adapted to measure one or more physical phenomena associated with a type of geophysical data. Some of the transducers coupled to a same geophysical data acquisition device may be of the same type, e.g. electrical current sensors, as long as at least one of the transducers is of a different type from at least another one of the transducers, the at least two transducers of a different type being adapted to measure physical phenomena associated with respective different types of geophysical data.

In one embodiment, the geophysical data acquisition and processing system further comprises a control server for controlling the plurality of geophysical data acquisition devices. The processor of each geophysical data acquisition device may be configured to receive command or parameter information from the control server to simultaneously process signals received from the respective set of transducer signal receivers corresponding to the respective selection of transducers.

In one embodiment, the wireless receiver of each geophysical data acquisition device is 5 configured to receive command or parameter information from the same external device.

The control server may be part of the external device. Alternatively, or simultaneously, the processing server may be part of the external device.

In one embodiment, the time base element of each geophysical data acquisition device is adapted to generate an output signal usable by the respective analog-to-digital converter for simultaneously digitising the signals received from a respective set of the plurality of different transducers and wherein the signals received from respective sets of transducers at a first and a second geophysical data acquisition devices are digitised in synchronisation.

In one embodiment, the geophysical data processing server is configured to wirelessly receive the transducer data from the plurality of geophysical data acquisition devices. In this embodiment, the processor of each geophysical data acquisition device may be arranged to compress the transducer data, wherein the geophysical data processing server is configured to wirelessly receive the transducer data from the plurality of geophysical data acquisition devices in a compressed form.

In one embodiment, the geophysical data processing server is configured to wirelessly receive the transducer data via a low-power wide-area communications network.

In one embodiment, the geophysical data processing server is configured to simultaneously process a set of transducer data received from a selection of geophysical data acquisition devices.

In one embodiment, the geophysical data acquisition and processing system further comprises an excitation information server for receiving excitation information, and the geophysical data processing server is configured to simultaneously process the set of transducer data using the excitation information.

In one embodiment, the geophysical data acquisition and processing system comprises at least one hundred geophysical data acquisition devices.

In one embodiment, the geophysical data acquisition and processing system is arranged to function in a mode that may be referred to as “data logger” mode, whereby the control server is configured to send command or parameter information to the plurality of geophysical data acquisition devices, the command or parameter information comprising instructions associated with a period of time during which the processor of each geophysical data acquisition device is to process signals digitised at a specified rate over a specified time period with a specified gain. The “data logger” mode may, for example, be advantageous in the event that both wireless and hardwired network options are precluded or impractical.

It will be understood that it is envisaged that the geophysical data processing server and the control server may be part of different external devices. It is further envisaged that a first group of geophysical data acquisition devices may be configured to receive command or parameter information from a first external device and that a second group of geophysical data acquisition devices be configured to receive command or parameter information from a second external device. The geophysical data processing server may be in communication with the first and second external devices to receive and process the transducer data from the plurality of geophysical data acquisition devices. Other arrangements and embodiments as may be found appropriate to a person skilled in the art are also envisaged.

Embodiments of the present invention may be applicable to geophysical surveys as a result of naturally occurring or controlled excitation sources. For naturally occurring excitation sources, bandwidths of measurements may span a frequency range between 10³ Hz to roughly 300 Hz, and particular applications may have a bandwidth between 10⁴ Hz and 30 kHz. While natural field signals may be hampered by two persistent low signal “dead bands” spanning 0.05 Hz to 1.0 Hz and 400 Hz to 4 kHz, the front end analog signal conditioning provided in accordance with embodiments of the present invention may allow mitigating such dead-band challenges.

For controlled excitation sources, example excitations may include periodic and polarity-symmetric current excitation waveforms, square waveforms with a range of duty cycles, and impulsive to 100% duty. To effectively serve the bandwidths of such controlled excitations, multiple different excitation base frequencies and duty cycles may be used. An interesting aspect of polarity-symmetric waveforms is that multiple excitations can be simultaneously engaged providing they are uncorrelated with each other. The geophysical data acquisition device may be arranged to carry out front-end analog signal conditioning using algorithms designed such that 1 Hz and 2 Hz base-frequency excitations do not interfere with each other.

In one embodiment, the geophysical data acquisition device comprises a data storage for storing the command or parameter information received from the external device, the received excitation information, the digitised signals output from the analog-to-digital converter, and the transducer data. The data storage may comprise one or more storage media for storing, respectively, the command or parameter information, the received excitation information, data associated with the digitised signals output from the analog-to-digital converter including timestamps, and the transducer data.

One or more storage media of the data storage may be configured to have relatively high write speeds depending on the sampling rate to keep up with the output digitised signals for all channels, i.e. all transducer signal receivers. For example, a storage medium of the data storage may be configured to have a write speed in a range between 1 million bytes per second (MB/s) and 100 MB/s. However, it will be understood that any other write speed is envisaged, as may be deemed appropriate by a person skilled in the art. The data storage may comprise one or more fast storage media and may further comprise non-volatile memory for permanently storing, for example however not limited to, computer program instructions usable by the processor. In one embodiment, the data storage may include one or more high-speed memory buffers and a non-volatile memory wherein data (including the command or parameter information, the received excitation information, data associated with the digitised signals output from the analog-to-digital converter including timestamps, and the transducer data) can be written to the high-speed memory buffers during the data acquisition, i.e. as the data are acquired, and can then simultaneously be transferred to the permanent non-volatile memory at a slower writing speed.

The geophysical data acquisition device and geophysical data acquisition and processing system in accordance with embodiments of the present invention seek to provide the following advantages:
Wireless networking design and capabilities
Toughness, reliability in field operation conditions
Low Mass and power consumption (power consumption dictates battery mass)
Low Production cost
Strong Measurement fidelity
Uniform and self-consistent time base (GPS and/or wireless)
Geophysical flexibility (range of survey and measurement classes served)
Networked and non-networked (autonomous) operational modes
Ease of use (reliability, packing geometry, transportation, connectors, etc.)
Robust, insightful state-of-health monitoring and reporting

### BRIEF DESCRIPTION OF THE DRAWINGS

Notwithstanding any other forms which may fall within the scope of the disclosure as set forth in the Summary, specific embodiments will now be described, by way of example only, with reference to the accompanying drawings in which:

FIG. 1 is a schematic block diagram of a geophysical data acquisition device in accordance with an embodiment;

FIG. 2 is a schematic block diagram of a geophysical data acquisition and processing system in accordance with an embodiment; and

FIG. 3 is a schematic representation of a geophysical data acquisition and processing system in accordance with an embodiment.

### DETAILED DESCRIPTION OF AN EMBODIMENT

In the following, same or similar features or elements will be represented and described using same reference numerals.

In one embodiment, the geophysical data acquisition device 10 is arranged for acquiring and processing signals from different transducers as a result of either natural field excitation sources or controlled man-made excitation sources.

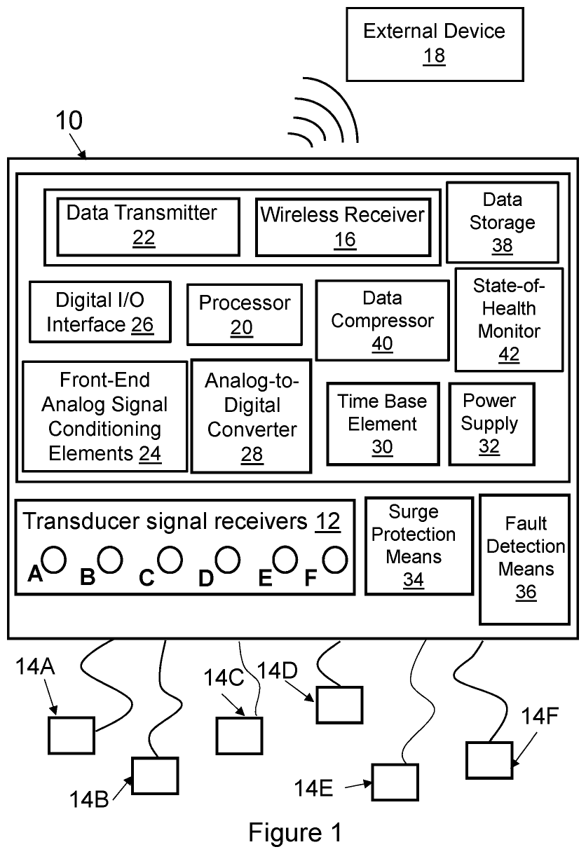

FIG. 1 shows a schematic block diagram of a geophysical data acquisition device 10 for acquiring and processing signals from different transducers in accordance with an embodiment of the present invention.

The geophysical data acquisition device 10 comprises six transducer signal receivers 12A, 12B, 12C, 12D, 12E, 12F configured to receive signals from six different transducers 14A, 14B, 14C, 14D, 14E, 14F respectively. In the following, the transducer signal receivers 12A, 12B, 12C, 12D, 12E, 12F and transducers 14A, 14B, 14C, 14D, 14E, 14F will also be referred to more generally as transducer signal receiver 12 or transducer signal receivers 12, and transducer 14 or transducers 14. The geophysical data acquisition device 10 further comprises a wireless receiver 16 for wirelessly receiving command or parameter information from an external device 18. The geophysical data acquisition device 10 further comprises a processor 20 configured to, based on the received command or parameter information, determine a selection of transducers 14 from the plurality of transducers (in this example a selection of transducers out of the six transducers 14A, 14B, 14C, 14D, 14E, 14F) and process the signals received by each of a set of transducer signal receivers 12 corresponding to the selection of transducers 14 into transducer data corresponding to the transducer 14 associated with the transducer signal receiver 12. The geophysical data acquisition device 10 further comprises a data transmitter 22 configured to transmit the transducer data to the external device 18. Each of the transducers 14 is adapted to measure one or more physical phenomena associated with a set and type of geophysical data, wherein the type of geophysical data associated with the one or more physical phenomena measured by at least one of the six transducers 14 is different to the type of geophysical data associated with the one or more physical phenomena measured by at least another one of the transducers 14.

For example, the transducer 14A may be adapted to measure physical phenomena associated with electric field data, the transducer 14B may be adapted to measure physical phenomena associated with magnetic field data, the transducer 14C may be adapted to measure physical phenomena associated with electrical current data, the transducer 14D may be adapted to measure physical phenomena associated with seismic data, and transducers 14E and 14F may be adapted to measure physical phenomena associated with any one of electric field, magnetic field data, electrical data, and seismic data.

It will be understood that each transducer may however be any transducer and may be any type of transducer adapted to measure one or more physical phenomena associated with any type of geophysical data.

Some of the transducers coupled to a same geophysical data acquisition device may be of the same type, e.g. electrical current transducers, as long as at least one of the transducers coupled to a same geophysical data acquisition device is of a different type from at least another one of the transducers, wherein each of the at least two transducers of a different type is adapted to measure physical phenomena associated with a respective different type of geophysical data.

In one embodiment, the external device 18 is a computer located at a central control facility wherein an operator governs operations and monitors data quality. The central control facility may also be referred to in the following as a base station.

In an alternative embodiment, the external device 18 is a relay station (such as, e.g., a gateway, a hub, a node, or a repeater) acting as an intermediary between the geophysical data acquisition device 10 and a central control facility. The external device 18 as a relay station may be arranged to boost incoming and/or outgoing signals between the geophysical data acquisition device 10 and the central control facility.

In another alternative embodiment, the external device 18 may be a local device communicating with the geophysical data acquisition device 10. For example, the external device 18 may be a lightweight handheld ruggedized computer either under the control of a crewperson or, alternatively, mounted to an unmanned airborne or ground vehicle.

In one embodiment, the data transmitter 22 is configured to wirelessly transmit the transducer data to the external device 18.

In one embodiment, the geophysical data acquisition device 10 is arranged to be suitable for acquiring and processing signals from a wide range of different types of transducers, including:
electric field transducers such as, however not limited to, a grounded dipole (measures a voltage between two separated electrodes in the ground), or an ungrounded dipole (uses charge-coupled amplifiers);
magnetic field transducers such as, however not limited to, a large area (e.g. 100 m²) single-turn induction loop, multi-turn passive induction coils, multi-turn active (amplified) induction coils, current-amplified search coils, flux-feedback search coils, fluxgate magnetometers, optically pumped alkali vapor total field magnetometers, high-temperature and low-temperature SQUID magnetometers, or spintronics giant magneto-resistive (GMR);
electrical current transducers such as, however not limited to, shunt and Kelvin (four-terminal) resistors, zero-flux fluxgate detectors, Hall effect sensors, or a Rogowski coil;
ground motion transducers such as, however not limited to, a mechanical geophone, or various classes of accelerometers both single component and 3-component.

In one embodiment, one or more of the transducers 14 are equipped with their own respective isolated power supply. In one embodiment, each transducer signal receiver 12 of the geophysical data acquisition device 10 is equipped with its own respective power supply, and the power supplies of all transducer signal receivers 12 are coupled to a same battery.

It is noted that FIG. 1 is only intended to be schematic and does not represent any element of the geophysical data acquisition device 10, arrangement of transducers 14 and external device 18 at scale.

It will be understood that embodiments of the present invention are not limited to the geophysical data acquisition device 10 comprising six transducer signal receivers and an arrangement with six transducers. It is envisaged for example that the geophysical data acquisition device 10 comprises any number of transducer signal receivers and transducers, and may comprise in some example however without any limitation, at least 4 transducer signal receivers or between 4 and 8 transducer signal receivers.

Further, in the following, the signals received from the transducers 14 at the transducer signal receivers 12 may interchangeably be referred to as “transducer signals”.

The command or parameter information received from the external device 18 may include a set of instructions associated with the selection of transducers 14 wherein the processor 20 is configured to use the set of instructions to determine the selection of transducers 14 from the plurality of transducers and signals from which transducer signal receivers 12 are to be processed.

For example, the set of instructions received may cause the processor 20 to determine transducers 14A, 14B, 14C and 14D, and to process the signals received by each of the transducer signal receivers 12A, 12B, 12C and 12D corresponding, respectively, to the selection of transducers 14A, 14B, 14C and 14D. In one embodiment, the processor 20 is configured, based on the received command or parameter information, to simultaneously process the signals received by the set of transducer signal receivers 12 corresponding to the selection of transducers 14. In one embodiment, the geophysical data acquisition device 10 is equipped with software comprising executable program instructions wherein the processor 20 is configured to execute the program instructions to simultaneously process the signals received by the set of transducer signal receivers 12.

In one embodiment, the transducers 14 are all configured to produce an analog voltage output in response to some excitation source and the geophysical data acquisition device 10 comprises a front-end analog signal conditioning means 24. The front-end analog signal conditioning means 24 may be configured to ensure a commensurate level of noise cancellation and may comprise filtering elements, which may include low-pass filtering elements providing substantially linear and time-invariant low-pass filtering (e.g., approximately less than 10⁻⁶ non-linear distortion) at a number of selectable but fixed corner frequencies (e.g., four to eight selectable but fixed corner frequencies). In one embodiment, the corner frequencies of the linear low-pass filtering are commensurate with the sampling rate in use and the linear low-pass filtering has characteristics that are not impacted by the output impedance of the transducer being measured. The filtering elements may further include one or more high pass filtering elements, such as a 3 Hz high-pass filter, which may be appropriate for signal base frequencies greater than 10 Hz. In one embodiment, stable, time-invariant linear distortion (once a corner frequency is selected) is known in a substantially accurate manner to allow for a calibration of the digital signals in a substantially precise manner when referring to volts at the input.

The elements of the front-end analog signal conditioning means 24 are arranged to use respective algorithms to carry out the conditioning. In one embodiment, the front-end analog signal conditioning means 24 further comprises elements that provide a differential signal conditioning or amplification with common-mode rejection (e.g., >10⁶ (CMRR>120 dB)), and/or a small number of fixed gain stages yielding maximum allowable differential signal input levels of ±0.25V up to ±32V, and/or a chopper amplification with a specified chopper frequency and/or anti-aliasing protection. For example, a balanced, symmetric instrumentation for amplification may be used or any alternative means of amplification as would be deemed appropriate by a person skilled in the art.

In one embodiment, the signals output by the transducers 14 are received by the transducer signal receivers 12 with a constant and frequency-independent input impedance. For example, a constant and frequency-independent input impedance of approximately 10⁶Ω may be enabled at the transducer signal receivers 12. A stable input impedance may in particular be advantageous for measurements involving an acquisition of electrical field data, wherein a grounded dipole may be used as a transducer. Further, to ensure an appropriate level of input impedance and provide gain when needed in the front-end analog signal conditioning, the front-end analog signal conditioning means 24 may further comprise some operational amplifiers.

In another embodiment, the plurality of transducers 14 may comprise at least some transducers 14 that are configured to generate a digital signal. In this embodiment, the geophysical data acquisition device 10 further comprises a digital I/O interface 26 configured to receive and store the digital signal data received from the transducers 14 by the transducer signal receivers 12.

In one embodiment, the geophysical data acquisition device 10 further comprises an analog-to-digital converter 28 arranged to digitise the signals received from the plurality of different transducers 14. In the following, the terms “digitise”, “digitised”, “sample” and “sampled” will be used interchangeably to refer to the process of converting signals received from the transducers 14 in an analog form into a digital form, wherein the conversion involves quantization of the signals received from the transducers 14. The quantization is characterised by a sampling rate. In one embodiment, the analog-to-digital converter 28 is arranged to digitise the signals received at the set of transducer signal receivers using sigma-delta modulation. Sigma-delta modulation may be advantageous to act as an anti-aliasing filter in order to help maximize the fidelity of the geophysical data acquisition device 10 in its acquisition and processing of transducer signals. Alternatively, other approaches may be used for carrying out the digitization of the signals.

In some embodiments, the sampling rates at which the signals received by each of the transducer signal receivers 12 from transducers 14 are digitised may range from 1 to 10⁵ up to 2×10⁵ samples-per-second (sps). For example, a maximum sampling rate of between 10⁴ and 10⁵ sps may serve most base-metals exploration surveys. However, it will be understood that sampling rates higher than 2×10⁵ sps are not excluded and may be considered.

In one embodiment, the geophysical data acquisition device 10 further comprises a time base element 30, which is adapted to generate an output signal usable by the analog-to-digital converter 28 for simultaneously digitising the signals received from the plurality of different transducers 14. In one embodiment, the time base element 30 is provided in the form of a slaved oscillator arranged to receive a time signal from a Global Navigation Satellite System (GNSS) or a Global Positioning System (GPS) (e.g., GNSS (or GPS) 1 pulse-per-second (PPS) time signal which is satellite time based and is relatively robust and low-cost). Alternatively, the time base element 30 may be a time base generator arranged to receive a time signal in the form of a relatively low-frequency (<100 MHz) radio signal that is not disrupted by mountainous topography and is unencumbered by international licensing requirements may be used. In response to receiving the time signal, the time base element 30 is then arranged to generate an output signal indicative of a sampling rate, the output signal causing the analog-to-digital converter 28 to simultaneously digitise the transducer signals. In other words, the output signal causes the analog-to-digital converter 28 to digitise the transducer signals at substantially the same sampling rate.

Further, in one embodiment, the analog-to-digital converter 28 is configured to sample, i.e. digitise the transducer signals in synchronisation with the excitations. To achieve sampling simultaneity and synchronisation of the sampling process with the excitations, the sampling rate must correspond to an integer number of samples per half-period associated with the excitation signal. In one embodiment, the transducer signals comprise respective transducer response signals received from the transducers as a result of the excitation and respective excitation signals. In one embodiment, the excitation signals convey information associated with the source and type of the excitation, such as, however not limited to, excitation base frequency, time at which the excitation started, duration of excitation, time at which the excitation stopped. In one embodiment, an excitation signal is transmitted by a transmitter of the excitation source hardware to the transducers 14, wherein the geophysical data acquisition device 10 may be at or in the proximity of the excitation source hardware and transmitter. The excitation source hardware may comprise one or more excitation control devices that establish transmitter settings such as, waveform, base frequency, optimal voltage level, start and stop times, etc. In one embodiment, the excitation signal is periodically received from the transducers 14 at the transducer signal receivers 12. The analog-to-digital converter 28 is arranged to digitise the transducer response signals at substantially the same sampling rate and to digitise the transducer response signals and the excitation signals in synchronisation using a signal processing algorithm (which may be referred to as odd-harmonic stacking) wherein the transducer response signals and the excitation signals are input into the signal processing algorithm. The processor 20 is then configured to determine a selection of the transducers 14 using the commands or parameter information received from the external device 18, and to simultaneously process the digitised transducer response signals and the digitised excitation signals for the selected transducers 14 into transducer data comprising transducer response data and excitation data.

Alternatively, or simultaneously, the wireless receiver 16 may further be arranged to receive excitation information and wherein the processor 20 is configured to use the received excitation information to process the digitised transducer response signals (transducer response signals digitised at substantially the same sampling rate) corresponding to the selection of transducers 14 simultaneously and in synchronisation with the excitation information. In this embodiment, the excitation information may be received from another geophysical data acquisition device 10 positioned to measure the same excitation. Alternatively, the excitation information may be received from the excitation source hardware via a wireless communication means such as a wireless communications network or, wherein distances allow, using wireless technology such as Bluetooth® or any other alternative short-range wireless means of technology. In another alternative embodiment, the excitation information may be received at the wireless receiver 16 from the external device 18 via a wireless communications network or, wherein distances allow, using wireless technology such as Bluetooth® or any other alternative short-range wireless means of technology.

In one embodiment, each transducer 14 is connected to the geophysical data acquisition device 10 by means of a wire connection. In some embodiments, at least some of the transducers 14 may be configured to wirelessly receive and/or transmit data from/to the geophysical data acquisition device 10 and/or the external device 18. For example, local wireless communications may be enabled between the geophysical data acquisition device 10 and transducers 14 with selectable settings wherein it is possible, for example, to remotely switch between two or more different transducers 14, to remotely disconnect wires & cables because of local lightning activity, to remotely set off a hidden external alarm if theft is suspected. In this embodiment, the geophysical data acquisition device 10 may be arranged to receive commands from the external device 18 at the wireless receiver 16, wherein the received commands cause the processor 20 to determine a new selection of transducers 14. In the embodiment wherein the received commands are indicative of instructions to disconnect a connection between the geophysical data acquisition device 10 and the transducers 14, the processor 20 may further be configured to generate an output signal using the received commands. In the embodiment where the transducers 14 are connected to the geophysical data acquisition device 10 by means of a wire connection, the output signal may be used by the digital I/O interface 26 to cause one or more of the transducer signal receivers 12 to disconnect or interrupt the wire connection to the transducers 14. Alternatively, where the transducers 14 are configured to wirelessly receive and/or transmit data, the output signal generated by the processor may be wirelessly transmitted to the transducers 14 causing the transducers 14 to stop measuring.

In one embodiment, the wireless receiver 16 and data transmitter 22 are part of one unit having wireless transmission and receiving capabilities.

It will be understood that embodiments of the present invention are not limited to the command or parameter information being associated with a selection of four transducers and/or four different types of transducers. The command or parameter information may be associated with a selection of any number of the transducers and corresponding transducer signal receivers of the geophysical data acquisition device 10.

The geophysical data acquisition device 10 generally is equipped with some power supply 32. In one embodiment, the total power consumption of the geophysical data acquisition device 10 when sampling all signals from all selections of transducers 14 may remain substantially low.

The geophysical data acquisition device 10 may further comprise a surge protection means 34 to provide robust surge protection during use when the geophysical data acquisition 10 is either active or inactive. Further, the geophysical data acquisition device 10 may comprise a fault detection means 36 having the ability to detect, in use, certain pathologies such as faulty components or signal overscaling. The surge protection means 34 and fault detection means 36 may for example be appropriate to protect the electronics of the geophysical data acquisition device 10 from static discharges or surges such as from nearby atmospheric electrical activity.

The front-end analog signal conditioning in accordance with embodiments of the present invention is arranged to maintain linearity in the signal processing wherein fidelity and resulting accuracy in the processing of the received signals can be achieved and precision and accuracy in the subsequent extraction of the geophysical data can be substantially improved.

The front-end analog signal conditioning in accordance with embodiments of the present invention aims at providing an accuracy of the signal acquisition and processing process that is improved by an order of magnitude when calculating volts referred to input in comparison to the front-end analog signal conditioning in known geophysical data acquisition devices.

In one embodiment, the geophysical data acquisition device 10 comprises a data storage 38 for storing the command or parameter information received from the external device 18, the received excitation information, the digitised signals output from the analog-to-digital converter 28, and the transducer data. The data storage 38 may comprise one or more storage media for storing, respectively, the command or parameter information, the received excitation information, data associated with the digitised signals output from the analog-to-digital converter 28 including timestamps, and the transducer data.

One or more storage media of the data storage 38 may be configured to have relatively high write speeds depending on the sampling rate to keep up with the output digitised signals for all channels, i.e. all transducer signal receivers 12. For example, a storage medium of the data storage 28 may be configured to have a write speed in a range between 1 million bytes per second (MB/s) and 100 MB/s. However, it will be understood that any other write speed are envisaged, as may be deemed appropriate by a person skilled in the art. The data storage 38 may comprise one or more fast storage media and may further comprise non-volatile memory for permanently storing, for example however not limited to, computer program instructions usable by the processor 20. In one embodiment, the data storage 38 may include one or more high-speed memory buffers and a non-volatile memory wherein data (including the command or parameter information, the received excitation information, data associated with the digitised signals output from the analog-to-digital converter 28 including timestamps, and the transducer data) can be written to the high-speed memory buffers during the data acquisition, i.e. as the data are acquired, and can then simultaneously be transferred to the permanent non-volatile memory at a slower writing speed. Further, it will be understood that any data storage and data storage arrangement as may deemed appropriate by the person skilled in the art is considered to be within the scope of the present disclosure.

Embodiments of the present invention further seek to provide a geophysical data acquisition device 10 that is advantageous when in use for simultaneous acquisition and processing of different types of geophysical data in fields covering large survey areas (e.g. between 10 and 2,000 km²) and consequently large distances with substantially high accuracy and precision.

The geophysical data acquisition device 10 in accordance with embodiments of the present invention is arranged to acquire a large number of signals from a number of different transducers and to process a corresponding large amount of data, including data relating to different types of geophysical data. In one embodiment, to allow for a transmission of the transducer data wirelessly over large distances while maintaining accuracy and precision of the transducer data and with minimal loss of data, wireless communication between the external device 18 and the geophysical data acquisition device 10 is enabled via a low power wide area communications network (LPWAN). An LPWAN may indeed be particularly advantageous for long-range, multi-hop wireless communications between a geophysical data acquisition device 10 and the external device 18.

Further, in one embodiment, the transducer data are compressed prior to transmission to the external device 18. In this embodiment, the processor 20 further comprises a data compressor 40 that is configured to compress the transducer data using one or more data compression schemes providing substantially lossless compression optimised for integer time-series. The data compression aims at yielding maximized effective information content in a relatively small number of bytes. For example, in a specific example, a plurality of gigabytes of transducer data may be compressed using one or more data compression schemes to a single bit either 0 or 1, with 0 meaning that the transducer data are corrupted, i.e. not valuable, and 1 meaning that the data are good, i.e. valuable. The data compression further aims at facilitating a transmission of the transducer data to the external device 18 via an LPWAN, which must be slow to reserve power, while serving quality assurance requirements over long distances.

In the embodiment where the transducer signals comprise respective transducer response signals received from the transducers 14 (as a result of the excitation) and respective excitation signals, the data compressor 40 may be configured to compress the transducer response data and the excitation data using one or more data compression schemes providing substantially lossless compression optimised for integer time-series. In this embodiment, the data transmitter 22 may be configured to wirelessly transmit the compressed transducer response data and compressed excitation data to the external device 18 and the transducer excitation data may be further transmitted to another geophysical data acquisition device 10.

In one embodiment, the geophysical data acquisition device 10 is configured to acquire and process the signals received from the transducers 14 into transducer data in real-time, on-the-fly.

In another embodiment where distances between the geophysical data acquisition device 10 and the external device 18 are relatively short-range, communications between the geophysical data acquisition device 10 and the external device 18 may be facilitated using Bluetooth® technology, or alternatively any other short-range, wireless means of technology.

Such enabled communication may be used for example in an embodiment wherein the external device 18 is an operator's wireless device or unmanned aerial vehicle.

In one embodiment, it is also envisaged that the geophysical data acquisition device 10 and the external device 18 be in network communication via hardwire connection. Network communication via hardwire connection may be enabled via an Ethernet cable, serial or parallel cable, or any other means as deemed appropriate by a person skilled in the art.

Network communication via hardwire connection between the geophysical data acquisition device 10 and the external device 18 may be advantageously used for high station density operational modes where the ground is imaged with maximum resolution and contiguous dipoles are employed as transducers for example.

The geophysical data acquisition device 10 may further be equipped with a state-of-health monitor 42 configured to carry out state-of-health monitoring using respective state-of-health algorithms. The state-of-health monitor 42 may be configured to carry out monitoring of the following, the list being non-exclusive:
battery voltage and expected remaining life
power supplies and various voltage checks
network (when active)
ADC built in self-checks
sensor impedance (generally on-command)
over-scales (high side and low side)
integrity of essential files (e.g. SHA-256 hash signatures)
internal memory integrity
surge-protection circuitry

Further, the geophysical data acquisition device 10 may be arranged to function according to various modes of operation including:
a listening while sleep mode
a listening while active mode
a timed off mode
a networked mode
an autonomous mode (logger—no network communications)
a reduced power mode (e.g. a selection of transducers disabled)

The term “sleep mode” may also be referred to as inactive mode.

The term “active” in the context of this application is intended to mean:
a) the geophysical data acquisition device 10 is turned on and fully functioning, able to acquire and store data, with network communications enabled; or
b) the geophysical data acquisition device 10 is turned off to save power but the network communications are enabled; or
c) the network communications are disabled (timed off) but the geophysical data acquisition device 10 is turned on and fully functioning.

A networked mode is intended to mean that network communications are enabled.

In one embodiment, the data storage 38 is further configured to store data associated with the state of heath information, fault reports, battery history, communications/network health, internal temperature, and any other data received and/or processed within the geophysical data acquisition device 10.

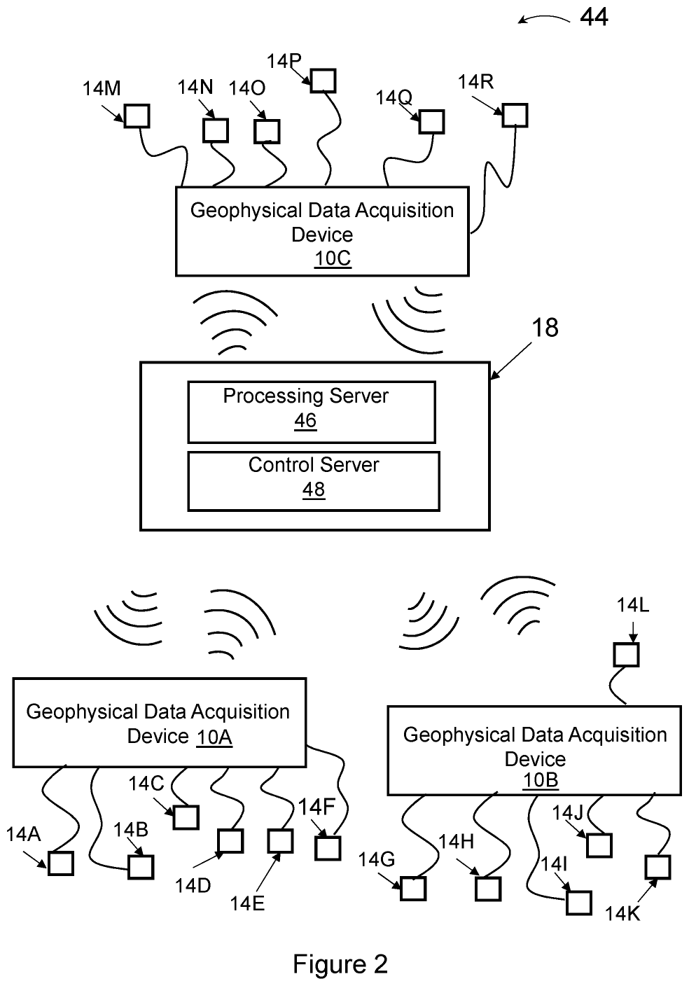

FIG. 2 shows a schematic block diagram of a geophysical data acquisition and processing system 44 in accordance with an embodiment. The geophysical data acquisition and processing system 44 comprises a plurality of transducers 14, each transducer 14 being adapted to measure one or more physical phenomena associated with a set and type of geophysical data, wherein the one or more physical phenomena measured by at least one transducer of the plurality of transducers are associated with a type of geophysical data that is different to the type of geophysical data associated with the one or more physical phenomena measured by at least another transducer of the plurality of transducers. The geophysical data acquisition and processing system 44 further comprises a plurality of geophysical data acquisition devices 10, each geophysical data acquisition device 10 being for acquiring and processing signals from a set of the plurality of transducers 14 into transducer data, and each geophysical data acquisition device 10 being in accordance with embodiments of the present invention as described above. The geophysical data acquisition and processing system 44 further comprises a geophysical data processing server 46 configured to receive and process the transducer data from the plurality of geophysical data acquisition devices 10. In a specific embodiment, the geophysical data processing server 46 is configured to wirelessly receive the transducer data from the plurality of geophysical data acquisition devices 10.

In the embodiment illustrated in FIG. 2, the geophysical data acquisition and processing system 44 comprises three geophysical data acquisition devices 10A, 10B, and 10C, each geophysical data acquisition device 10A, 10B, and 10C being arranged to receive signals from six transducers, respectively: 14A, 14B, 14C, 14D, 14E, 14F; 14G, 14H, 14I, 14J, 14K, 14L; 14M, 14N, 14O, 14P, 14Q, 14R.

In this embodiment illustrated in FIG. 2, the wireless receiver of each geophysical data acquisition device 10A, 10B, 10C is configured to receive command or parameter information from the same external device 18 and the geophysical data processing server 46 is part of the external device 18.

The geophysical data acquisition and processing system 44 further comprises a control server 48 for controlling the plurality of geophysical data acquisition devices 10. In this example, the control server 48 is part of the external device 18.

The processor 20 of each geophysical data acquisition device 10A, 10B, 10C is configured to receive command or parameter information from the control server 48, wherein, in accordance with the received command or parameter information, the processor 20 is configured to simultaneously process signals received from the respective set of transducer signal receivers 12 corresponding to the respective selection of transducers 14, as described above.

In one embodiment, the geophysical data acquisition and processing system 44 is arranged to function in a mode that may be referred to as “data logger” mode, whereby the control server 48 is configured to send command or parameter information to the plurality of geophysical data acquisition devices 10, the command or parameter information comprising instructions associated with a period of time during which the processor 20 of each geophysical data acquisition device 10 is to process signals digitised at a specified rate over a specified time period with a specified gain. The “data logger” mode may, for example, be advantageous in the event that both wireless and hardwired network options are precluded or impractical.

It will be understood that it is envisaged that the geophysical data processing server 46 and the control server 48 be part of different external devices. It is further envisaged that a first group of geophysical data acquisition devices 10 be configured to receive command or parameter information from a first external device and that a second group of geophysical data acquisition devices 10 be configured to receive command or parameter information from a second external device, wherein the geophysical data processing server 46 may be in communication with the first and second external devices to receive and process the transducer data from the plurality of geophysical data acquisition devices 10. Other arrangements and embodiments as may be found appropriate to a person skilled in the art are also envisaged.

Further, although the system 44 has been described comprising three geophysical data acquisition devices 10A, 10B, and 10C, embodiments of the present invention seek to be applicable to a system 44 comprising any number of geophysical data acquisition devices 10, for example although not limited to, between 50 and 1,000 geophysical data acquisition devices 10. In one example, the geophysical data acquisition and processing system 44 may comprise at least one hundred geophysical data acquisition devices 10. It is also envisaged that the geophysical data acquisition and processing system 44 comprises more than 1,000 geophysical data acquisition devices 10.

In order to facilitate a two-way communication between the external device 18—including in one embodiment the geophysical data processing server 46 and control server 48—and the geophysical data acquisition devices 10 across long distances, a wireless communications network would be advantageous in comparison to a hardwired communications network wherein a large amount of wires would be required, which would involve transport of heavy equipment and inconvenience for an operator to install all geophysical data acquisition devices 10 across the survey area. In order to facilitate a two-way wireless communication between the external device 18—including in one embodiment the geophysical data processing server 46 and control server 48—and the geophysical data acquisition devices 10, with wireless transmission and reception of data over long distances, a substantially low-power wide-area communications network may be used. In one embodiment, the geophysical data processing server 46 is configured to wirelessly receive the transducer data via a low-power wide-area communications network. In one embodiment, to further facilitate wireless transmission of a high amount of transducer data from all geophysical data acquisition devices 10 to the external device 18, including in one embodiment the geophysical data processing server 46 and control server 48 using a low-power wide-area communications network, respective transducer data are in use transmitted by the data transmitters 22 of all geophysical data acquisition devices 10 in a compressed form.

In a further embodiment, a cellular approach may be employed wherein a limited number of strategically located and relatively large wattage “cell towers” are in direct communication with the geophysical data processing server 46 and/or control server 48, and also in direct communication with groups of geophysical data acquisition devices 10. Alternatively, or simultaneously, relay stations, satellites or other means as deemed appropriate by a person skilled in the art may be employed configured to communicate with the geophysical data processing server 46, the control server 48, and/or at least some of the plurality of geophysical data acquisition devices 10.

In one embodiment, some geophysical data acquisition devices 10 may further be arranged to communicate with one or more nearby geophysical data acquisition devices 10.

In one embodiment, geophysical data acquisition devices 10 that in use do not communicate with a cell tower, relay station, or satellite, may be arranged to self-route, via the one or more nearby geophysical data acquisition devices 10, to an appropriate neighboring cell tower, relay station, or satellite, or to the geophysical data processing server 46 and/or external device 18.

In another embodiment, it is envisaged that some neighboring geophysical data acquisition devices 10 be connected by means of single-conductor potential wires, such as for example however not limited to, optical or standard category (e.g. CAT 6) twisted-pair cables piggy-backed to form a network of a group of neighboring geophysical data acquisition devices 10 with high data rates and extremely low power.

Communications between the geophysical data processing server 46 and the plurality of geophysical data acquisition devices 10 may be enabled via a number of different communications network topologies.

In one embodiment, the communications network between the geophysical data processing server 46 and the plurality of geophysical data acquisition devices 10 may be a mesh network. Alternatively, it will be understood that other communications network topologies may be used, such as, e.g., a tree network, a ring network, a line network, a star network, a bus network, or a fully connected network.

In one embodiment, the geophysical data processing server 46 is configured to simultaneously process a set of transducer data received from a selection of geophysical data acquisition devices 10. In this embodiment, the set of transducer data may correspond to samples output by the respective processors 20 in synchronisation across the selection of geophysical data acquisition devices 10. For example, the data processing server 46 may be configured to receive command or parameter information from the control server 48 according to which the geophysical data processing server 46 is configured to determine a selection of geophysical data acquisition devices 10, for example, geophysical data acquisition device 10A and geophysical data acquisition device 10B, and to process the transducer data received from the selected geophysical data acquisition devices 10A and 10B. The selection of geophysical data acquisition devices 10 may correspond to geophysical data acquisition devices 10 associated with the respective selections of transducers 14, i.e. to the geophysical data acquisition devices 10 having in use received instructions to acquire and process signals from a respective selection of transducers 14. In other words, in use, not all geophysical data acquisition devices 10 may acquire and process signals from transducers. For example, command or parameter information sent from the external device 18 may comprise instructions for only the geophysical data acquisition device 10A and 10B to carry out measurements, wherein the geophysical data acquisition device 10C may be in stand-by.

In one embodiment, to facilitate the simultaneous sampling of the signals received from the set of transducer signal receivers across the selection of geophysical data acquisition devices 10 of the geophysical data acquisition and processing system 44 in synchronisation with respective excitation information from all active excitation sources (natural and manmade), excitation information is sent in a periodic manner to the selection of geophysical data acquisition devices 10. In one embodiment, the excitation information is sent in a compressed form, wherein raw excitation information data are compressed using a form of averaging such as stacking. In one embodiment, the transducer signals received by the transducer signal receivers 12 of one of the plurality of geophysical data acquisition devices 10 comprises transducer response signals and excitation signals. The analog-to-digital converter 28 of the geophysical data acquisition device 10 is configured to digitise the transducer response signals and the excitation signals in synchronisation as previously described. The processor 20 is configured to determine a selection of the transducers 14 using the commands or parameter information received from the control server 48, and to simultaneously process the digitised transducer response signals and the digitised excitation signals for the selected transducers 14 into transducer data comprising transducer response data and excitation data. The data compressor 40 is then configured to compress the transducer response data and the transducer excitation data using one or more data compression schemes providing substantially lossless compression optimised for integer time-series. In this embodiment, the data transmitter 22 of the geophysical data acquisition device 10 may be arranged to transmit the compressed excitation data to one or more geophysical data acquisition devices 10 of the plurality of geophysical data acquisition devices 10. The respective processors 20 of the one or more geophysical data acquisition devices 10 receiving the compressed excitation data are then configured to use the received compressed excitation data to process the digitised transducer response signals (transducer response signals digitised at substantially the same sampling rate) corresponding to the selection of transducers 14. In this embodiment, the processor 20 is configured to extract information from the received compressed excitation data and to process the digitised transducer response signals simultaneously and in synchronisation with the excitation information so as to generate the transducer data.

For synchronization of all samples between all geophysical data acquisition devices, the time base element 30 of each geophysical data acquisition device 10 may be equipped with a phase-locked loop with a low-frequency high-power broadcast timing (e.g. sinusoidal) signal.

For example, the timing signal may have a frequency range around 200 kHz although it will be understood that other frequency ranges as deemed appropriate to a person skilled in the art may be considered.

Further, it will be understood that different transducers 14 connected to respective geophysical data acquisition devices 10 may be arranged to measure physical phenomena as a result of a same excitation. In one embodiment, each analog-to-digital converter 28 is arranged to use a same signal processing algorithm to simultaneously digitize the signals received from transducers 14 measuring a same excitation and in synchronization with the excitation signal.

In one embodiment, the processing server 46 is configured to carry out modelling/inversion of all geophysical measurements, i.e. all selections of transducer data received from the selected geophysical data acquisition devices 10, simultaneously and substantially on-the-fly.

In one embodiment, in use, the command or parameter information may be broadcast between the control server 48 and the geophysical data acquisition devices 10 every few minutes to an hour, such as every 10 minutes, every 20 minutes, every 30 minutes or at any other rate as considered appropriate by a person skilled in the art. Further, in some embodiments, it is envisaged that the time required for the command or parameter information to be received by the respective geophysical data acquisition devices 10 after being sent by the control server 48 be no more than a few seconds, for example no more than 10 seconds, to assist with maintaining relatively high productivity of the system 40.

In one embodiment, compressed data (for example, up to 50,000 bits) are in use wirelessly transmitted from one geophysical data acquisition device 10 towards the processing server 46 at a rate not less than every few minutes, such as for example every 10 minutes, every 20 minutes, or every 30 minutes to an hour.

In one embodiment, the geophysical data acquisition and processing system 44 is arranged such that data are received within a shortest time possible after being transmitted so as to not hinder the productivity of operations and of the geophysical survey.

It is envisaged that the geophysical data acquisition device 10 in accordance with embodiments of the present invention be relatively light, and may for example weigh less than 2 kg, be not too bulky and easy to transport (e.g., have a maximum volume of approximately 3500 cm³ and have a maximum linear dimension of 30 cm), be operable in harsh conditions involving temperatures ranging from −40 C° to 50° C., pouring rain, and be substantially waterproof, e.g. waterproof in 50 cm of water or less.

Embodiments of the geophysical data acquisition device 10 and geophysical data acquisition and processing system 44, when applied to survey measurements of electric field, may be applicable to corresponding transducers with a variety of electrode geometries. For example, an arrangement of three electrodes serving two orthogonal dipoles, whereby one electrode serves both dipoles. Further, in another example, contiguous, shared-electrode dipoles whereby most dipoles employ electrodes that are also employed by two or more additional dipoles are envisaged. For example, one of any number of related geometries is N dipoles employing N+1 electrodes whereby all except the end-most electrodes are shared by two dipoles.

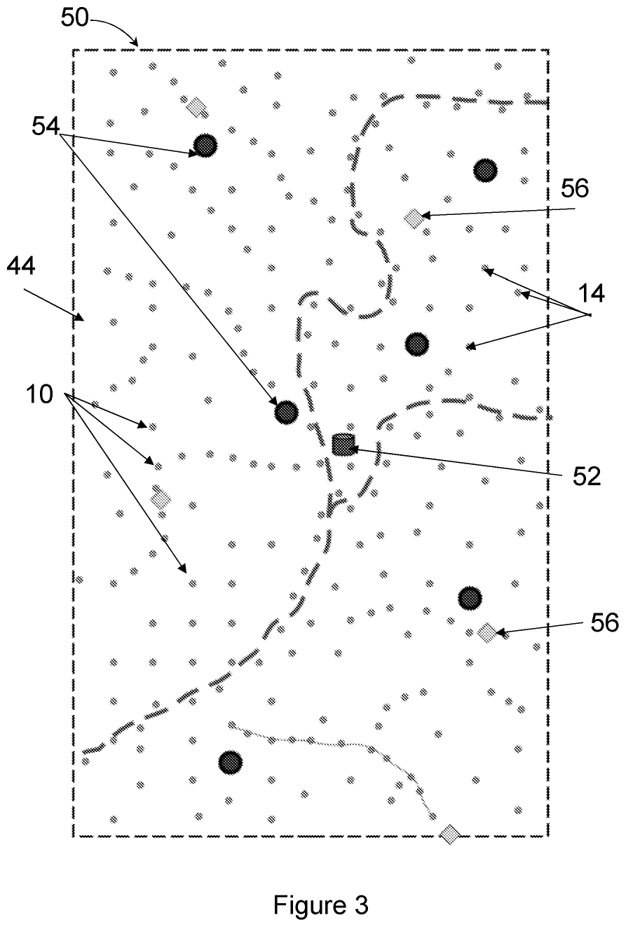

FIG. 3 shows an example implementation in accordance with an embodiment of the geophysical data acquisition and processing system 44 in a survey area 50 (not at scale). For example only, the survey area 50 may correspond to a topography in the Andes Mountains within the Atacama Desert and may have an area in the range of a few hundred up to a couple of thousands of km².

The geophysical data acquisition and processing system 44 comprises pluralities of transducers 14 and geophysical data acquisition devices 10 (represented with similar symbols in FIG. 3) that are provided in accordance with embodiments of the present invention. A control station 52 is provided, which in this embodiment comprises the geophysical data processing server 46 and control server 48. The control station 52 communicates with the plurality of geophysical data acquisition devices 10 using a wireless low-power wide area network (LPWAN). The control station 52 in use controls the operation of the geophysical data acquisition devices 10 in accordance with embodiments of the present invention, as described above.

Further, excitation stations 54 are indicated in FIG. 3. At these excitation stations 54, controlled time-varying magnetic and electric fields are generated, creating current flow in the subsurface. For example, at low frequencies the generated magnetic field signals serve a rarely employed geophysical method referred to as controlled-source magnetics and/or magnetic on-time electromagnetics (MoTEM). At higher frequencies, the generated magnetic fields induce eddy currents in the subsurface. The electric fields, employing current flow between two or more grounded electrodes, induce subsurface current flow at all frequencies.

Gateways, network hubs or relay stations 56 serving the wireless communications network in accordance with an embodiment of the present invention is also indicated. As described above, in a self-routing arrangement, a small number of these relay stations 56 (which may also be referred to as “cell towers” or “tethered drones”) may be arranged to communicate directly with a group of self-routing geophysical data acquisition devices 10 and with the control station 52.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features in various embodiments of the invention.

Modifications and variations as would be apparent to a skilled addressee are determined to be within the scope of the present invention.

1. A geophysical data acquisition device for acquiring and processing response signals that are generated by a plurality of transducers in response to a geophysical excitation inducing one or more physical phenomena associated with different types of geophysical data, wherein the transducers are adapted to measure the one or more physical phenomena and located in respective geographical regions local to the geophysical data acquisition device, the geophysical data acquisition device being in communication with a remote external device that is located in a geographical region that is remote to the plurality of transducers, and comprising:
a plurality of transducer signal receivers configured to receive the response signals from the plurality of transducers;
a wireless receiver configured to wirelessly receive command or parameter information from the remote external device;
a processor configured to, based on the received command or parameter information;
receive excitation information associated with excitation parameters characteristic of the geophysical excitation;
determine, from the plurality of transducers, a selection of transducers adapted to measure one or more physical phenomena associated with at least one of the different types of geophysical data; and
using the excitation information, process the response signals received by the transducer signal receivers corresponding to the selection of transducers to generate, for each response signal of the selection, respective transducer data corresponding to geophysical data; and
a data transmitter configured to transmit to the remote external device the generated transducer data obtained from the processing of the response signals received by the transducer signal receivers corresponding to the selection of transducers;
wherein the one or more physical phenomena measured by at least one transducer of the plurality of transducers are associated with a type of geophysical data that is different to the type of geophysical data associated with the one or more physical phenomena measured by at least another transducer of the plurality of transducers; and
wherein the geophysical data are usable to derive information on the physical properties of the Earth's surface and subsurface.

2. The geophysical data acquisition device of claim 1, wherein the geophysical data acquisition device further comprises an analog-to-digital converter arranged to digitize the response signals received from the plurality of transducers, the processor being configured to process, using the excitation information, the digitized response signals corresponding to the response signals received from the selection of transducers to generate, for each signal of the selection, the respective transducer data.

3. The geophysical data acquisition device of claim 2, wherein the geophysical data acquisition device further comprises a time base element adapted to generate an output signal usable by the analog-to-digital converter for simultaneously digitizing the response signals received from the plurality of transducers.

4. The geophysical data acquisition device of claim 1, wherein the processor is configured, based on the received command or parameter information and using the excitation information, to simultaneously process the response signals received by the transducer signal receivers corresponding to the selection of transducers.

5. The geophysical data acquisition device of claim 1, wherein the wireless receiver is arranged for wirelessly receiving excitation information from an external device.

6. The geophysical data acquisition device of claim 1, wherein the data transmitter is configured to wirelessly transmit the generated transducer data to the remote external device.

7. (canceled)

8. The geophysical data acquisition device of claim 6, wherein the data transmitter is configured to wirelessly transmit the generated transducer data to the remote external device using a wide-area communications network.

9. The geophysical data acquisition device of claim 1, wherein the geophysical data acquisition device further comprises a data storage for storing the command or parameter information.

10. (canceled)

11. The geophysical data acquisition device of claim 9, wherein the data storage is further arranged to store the received excitation information and the generated transducer data.

12. The geophysical data acquisition device of claim 1, comprising at least four transducer signal receivers, each transducer signal receiver being configured to receive signals from a respective transducer.

13. The geophysical data acquisition device of claim 1, wherein the type of geophysical data includes electric field data, magnetic field data, and electrical current data.

14. (canceled)

15. The geophysical data acquisition device of claim 1, wherein the plurality of transducers includes any one or more of the following types of transducers: an electric field transducer; a magnetic field transducer; and an electrical current transducer.

16. (canceled)

17. The geophysical data acquisition device of claim 1, further comprising a surge protection means.

18. The geophysical data acquisition device of claim 1, further comprising a fault detection means.

19. A geophysical data acquisition and processing system comprising:
a plurality of transducers adapted to generate response signals in response to a geophysical excitation inducing one or more physical phenomena associated with different types of geophysical data and adapted to measure the one or more physical phenomena, wherein the one or more physical phenomena measured by at least one transducer of the plurality of different transducers are associated with a type of geophysical data that is different to the type of geophysical data associated with the one or more physical phenomena measured by at least another transducer of the plurality of transducers;
a plurality of geophysical data acquisition devices, each geophysical data acquisition device being connected to a respective set of transducers of the plurality of transducers, and
wherein each geophysical data acquisition device acquires and processes response signals that are generated by a plurality of transducers in response to a geophysical excitation inducing one or more physical phenomena associated with different types of geophysical data, wherein the transducers are adapted to measure the one or more physical phenomena and located in respective geographical regions local to the geophysical data acquisition device, the geophysical data acquisition device being in communication with a remote external device that is located in a geographical region that is remote to the plurality of transducers, and comprising:
a plurality of transducer signal receivers configured to receive the response signals from the plurality of transducers;
a wireless receiver configured to wirelessly receive command or parameter information from the remote external device;
a processor configured to, based on the received command or parameter information:
receive excitation information associated with excitation parameters characteristic of the geophysical excitation;
determine, from the plurality of transducers, a selection of transducers adapted to measure one or more physical phenomena associated with at least one of the different types of geophysical data; and
using the excitation information, process the response signals received by the transducer signal receivers corresponding to the selection of transducers to generate, for each response signal of the selection, respective transducer data corresponding to geophysical data; and
a data transmitter configured to transmit to the remote external device the generated transducer data obtained from the processing of the response signals received by the transducer signal receivers corresponding to the selection of transducers;
wherein the one or more physical phenomena measured by at least one transducer of the plurality of transducers are associated with a type of geophysical data that is different to the type of geophysical data associated with the one or more physical phenomena measured by at least another transducer of the plurality of transducers; and
wherein the geophysical data are usable to derive information on the physical properties of the Earth's surface and subsurface; and
a geophysical data processing server configured to receive and process the generated transducer data transmitted from the plurality of geophysical data acquisition devices.

20. The geophysical data acquisition and processing system of claim 19, further comprising a control server for controlling the plurality of geophysical data acquisition devices.

21. The geophysical data acquisition and processing system of claim 20, wherein the processor of each geophysical data acquisition device is configured to receive command or parameter information from the control server to simultaneously process response signals received by the transducer signal receivers corresponding to the selection of transducers.

22. The geophysical data acquisition and processing system of claim 19, wherein the wireless receiver of each geophysical data acquisition device is configured to receive command or parameter information from the same remote external device.

23. The geophysical data acquisition and processing system of claim 22, further comprising a control server for controlling the plurality of geophysical data acquisition devices, wherein the control server is part of the remote external device.

24. The geophysical data acquisition and processing system of claim 19, wherein the geophysical data processing server is part of the remote external device.

25. The geophysical data acquisition and processing system of claim 40, wherein the at least some of the geophysical data acquisition devices further comprise a time base element adapted to generate an output signal usable by the respective analog-to-digital converter for simultaneously digitizing the response signals received from the plurality of transducers.

26. The geophysical data acquisition and processing system of claim 19, wherein the geophysical data processing server is configured to wirelessly receive the transducer data from the plurality of geophysical data acquisition devices.

27. (canceled)

28. The geophysical data acquisition and processing system of claim 19, wherein the geophysical data processing server is configured to wirelessly receive the generated transducer data via a wide-area communications network.

29. (canceled)

30. (canceled)

31. The geophysical data acquisition and processing system of claim 19, comprising at least one hundred geophysical data acquisition devices.

32. The geophysical data acquisition device of claim 2, wherein the analog-to-digital converter is further configured to digitize the received excitation information.

33. The geophysical data acquisition device of claim 3, wherein the analog-to-digital converter is further configured to digitize the received excitation information, and wherein the output signal is further usable by the analog-to-digital converter for digitizing the response signals received from the plurality of transducers and the excitation information in synchronization.

34. The geophysical data acquisition device of claim 1, wherein at least one transducer of the plurality of transducers is configured to measure excitation parameters characteristic of the geophysical excitation, the corresponding transducer signal receiver being configured to receive an excitation signal generated by the at least one transducer.

35. The geophysical data acquisition device of claim 34, wherein the processor is further configured to process the excitation signal to extract excitation data indicative of the excitation parameters characteristic of the geophysical excitation.

36. The geophysical data acquisition device of claim 5, wherein the external device is another geophysical data acquisition device comprising at least one transducer configured to measure excitation parameters characteristic of the geophysical excitation.

37. The geophysical data acquisition device of claim 1, wherein the data transmitter is further configured to transmit the excitation information to one or more other geophysical data acquisition devices.

38. The geophysical data acquisition and processing system of claim 19, wherein some transducers connected to a first geophysical data acquisition device and some transducers connected to a second geophysical data acquisition device are arranged to measure one or more physical phenomena induced by the same geophysical excitation.

39. The geophysical data acquisition and processing system of claim 19, wherein the processor of each geophysical data acquisition device is configured to periodically receive the excitation information.

40. The geophysical data acquisition and processing system of claim 19, wherein at least some of the geophysical data acquisition devices comprise an analog-to-digital converter arranged to digitize the response signals received from the plurality of transducers.

41. The geophysical data acquisition and processing system of claim 40, wherein the analog-to-digital converter is further configured to digitize the received excitation information.

42. The geophysical data acquisition and processing system of claim 25, wherein the output signal is further usable by the respective analog-to-digital converter for digitizing the response signals received from the respective plurality of transducers and the excitation information in synchronization.

43. The geophysical data acquisition and processing system of claim 19, wherein at least one geophysical data acquisition device comprises at least one transducer configured to measure excitation parameters characteristic of a respective geophysical excitation, the corresponding transducer signal receiver being configured to receive an excitation signal generated by the at least one transducer.

44. The geophysical data acquisition and processing system of claim 43, wherein the processor of the at least one geophysical data acquisition device is further configured to process the excitation signal to extract excitation data indicative of the excitation parameters characteristic of the respective geophysical excitation.

45. The geophysical data acquisition and processing system of claim 44, wherein the data transmitter of the at least one geophysical data acquisition device is configured to transmit the respective extracted excitation data to one or more other geophysical data acquisition devices of the plurality of geophysical data acquisition devices, the one or more other geophysical data acquisition devices being nearby the at least one geophysical data acquisition device.

46. A method of acquiring and processing response signals that are generated by a plurality of transducers in response to a geophysical excitation inducing one or more geophysical phenomena associated with different types of geophysical data, wherein the transducers are adapted to measure the one or more physical phenomena and located in respective geographical regions, wherein the one or more physical phenomena measured by at least one transducer of the plurality of transducers are associated with a type of geophysical data that is different to the type of geophysical data associated with the one or more physical phenomena measured by at least another transducer of the plurality of transducers, and wherein the geophysical data are usable to derive information on the physical properties of the Earth's surface and subsurface, the method comprising:
receiving, by the plurality of transducer signal receivers of a geophysical data acquisition device that is in communication with the plurality of transducers and that is local to the respective geographical regions, the response signals generated by the plurality of transducers in response to a geophysical excitation inducing one or more geophysical phenomena associated with different types of geophysical data;
wirelessly receiving, by a wireless receiver of the geophysical data acquisition device, command or parameter information from a remote external device that is in communication with the geophysical data acquisition device and that is located in a geographical region that is remote to the plurality of transducers;
receiving, by a processor of the geophysical data acquisition device, excitation information associated with excitation parameters characteristic of the geophysical excitation;
based on the receiving command or parameter information, determining, by the processor from the plurality of transducers, a selection of transducers adapted to measure one or more physical phenomena associated with at least one of the different types of geophysical data;
processing, by the processor and using the excitation information, the response signals received by the transducer signal receivers corresponding to the selection of transducers to generate, for each response signal of the selection, respective transducer data indicative of geophysical measurements usable to derive information on the physical properties of the Earth's surface and subsurface; and
transmitting, by the data transmitter and to the remote external device, the generated transducer data obtained from the processing of the response signals received by the transducer signal receivers corresponding to the selection of transducers.

47. The method of claim 46, further comprising digitizing the response signals received from the plurality of transducers and, by the processor and using the excitation information, processing the digitized response signals corresponding to the response signals generated by the selection of transducers to generate, for each signal of the selection, the respective transducer data.

48. The method of claim 46, further comprising digitizing the excitation information and simultaneously digitizing the response signals generated by the plurality of transducers in synchronization with the excitation information.

49. The method of claim 46, wherein at least one transducer of the plurality of transducers is configured to measure excitation parameters characteristic of the geophysical excitation, and wherein the method further comprises:
receiving, by a transducer signal receiver corresponding to the at least one transducer, an excitation signal; and
processing, by the processor, the excitation signal to extract excitation data indicative of the excitation parameters characteristic of the geophysical excitation.

50. The method of claim 46, further comprising receiving, by the wireless receiver, excitation information from an external device.

51. The method of claim 46, further comprising wirelessly transmitting, by the data transmitter, the generated transducer data to the remote external device.

52. A geophysical data acquisition device for acquiring and processing response signals that are generated by a plurality of transducers in response to a geophysical excitation inducing one or more physical phenomena associated with different types of geophysical data, wherein the transducers are adapted to measure the one or more physical phenomena and located local to the geophysical data acquisition device, the geophysical data acquisition device being in communication with a remote external device that is located remote to the plurality of transducers, and comprising:
a plurality of transducer signal receivers configured to receive the response signals from the plurality of transducers;
a wireless receiver configured to wirelessly receive command or parameter information from the remote external device;
a processor configured to, based on the received command or parameter information;
receive excitation information associated with excitation parameters characteristic of the geophysical excitation;
determine, from the plurality of transducers, a selection of transducers adapted to measure one or more physical phenomena associated with at least one of the different types of geophysical data; and
using the excitation information, process the response signals received by the transducer signal receivers corresponding to the selection of transducers to generate, for each response signal of the selection, respective transducer data indicative of geophysical measurements usable to derive information on the physical properties of the Earth's surface and subsurface; and
a data transmitter configured to transmit to the remote external device the generated transducer data obtained from the processing of the response signals received by the transducer signal receivers corresponding to the selection of transducers,
wherein the one or more physical phenomena measured by at least one transducer of the plurality of transducers are associated with a type of geophysical data that is different to the type of geophysical data associated with the one or more physical phenomena measured by at least another transducer of the plurality of transducers, and
wherein the geophysical data are usable to derive information on the physical properties of the Earth's surface and subsurface.
